(19) United States
(12) Patent Application Publication
(10) Pub. No.: US 2025/0246563 A1
(43) Pub. Date: Jul. 31, 2025

(54) PARTIALLY PULSE-PLATED BOND PADS

(71) Applicant: TEXAS INSTRUMENTS INCORPORATED, Dallas, TX (US)

(72) Inventors: Jomari AUSTRIA, Malabon City (PH); Jeffrey Salvacion SOLAS, Iloilo City (PH); Ray Fredric DE ASIS, Mabalacat (PH)

(21) Appl. No.: 18/428,472

(22) Filed: Jan. 31, 2024

(51) Int. Cl. H01L 23/00; H01L 23/31

(52) U.S. Cl. CPC H01L 24/05; H01L 23/3157; H01L 24/03; H01L 24/45; H01L 24/48; H01L 24/85; H01L 2224/0345; H01L 2224/03452; H01L 2224/04042; H01L 2224/05147; H01L 2224/05166; H01L 2224/05184; H01L 2224/05647; H01L 2224/45147; H01L 2224/48245; H01L 2224/48465; H01L 2224/85

(57) ABSTRACT

Example packages comprise a semiconductor die including a device side having circuitry; a metal member coupled to the device side; a copper member having a bottom surface coupled to the metal member and a top surface opposite the bottom surface, the copper member including at the top surface a nanotwin copper portion having a thickness between 0.5 microns and 3 microns, the copper member including a polycrystalline copper portion contacting the nanotwin copper portion and extending to the bottom surface, the nanotwin copper portion comprising a twin boundary separating a first region having a first grain structure from a second region having a second grain structure; a wire bond coupled directly to the nanotwin copper portion of the copper member, the wire bond contacting multiple regions of the nanotwin copper portion; and a mold compound covering the semiconductor die, the metal member, the copper member, and the wire bond.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. Dies are then coupled to a lead frame and are covered by a mold compound, which is subsequently sawn to produce a package.

### SUMMARY

Example packages comprise a semiconductor die including a device side having circuitry; a metal member coupled to the device side; a copper member having a bottom surface coupled to the metal member and a top surface opposite the bottom surface, the copper member including at the top surface a nanotwin copper portion having a thickness between 0.5 microns and 3 microns, the copper member including a polycrystalline copper portion contacting the nanotwin copper portion and extending to the bottom surface, the nanotwin copper portion comprising a twin boundary separating a first region having a first grain structure from a second region having a second grain structure; a wire bond coupled directly to the nanotwin copper portion of the copper member, the wire bond contacting multiple regions of the nanotwin copper portion; and a mold compound covering the semiconductor die, the metal member, the copper member, and the wire bond.

In examples, a method for manufacturing a package comprises sputtering a seed layer above a metal member, the metal member coupled to a semiconductor die; using photolithography to pattern a photoresist having a cavity above the metal member; forming a copper member in the cavity by direct plating a polycrystalline copper portion in the cavity and by pulse plating a nanotwin copper portion on the polycrystalline copper portion, the nanotwin copper portion occupying no more than 20% of a volume of the copper member; forming a wire bond on a top surface of the nanotwin copper portion using a wire bonder; and covering the semiconductor die and the copper member with a mold compound.

### BRIEF DESCRIPTION OF THE DRAWINGS

FIG. 1A is a profile, cross-sectional view of a package including direct copper wire bonding on a partially pulse-plated bond pad, in accordance with various examples.

FIG. 1B is a top-down view of a package including direct copper wire bonding on a partially pulse-plated bond pad, in accordance with various examples.

FIG. 1C is a perspective view of a package including direct copper wire bonding on a partially pulse-plated bond pad, in accordance with various examples.

FIG. 2 is a profile, cross-sectional view of a partially pulse-plated bond pad coupled to a wire bond, in accordance with various examples.

FIG. 3 is a flow diagram of a method for manufacturing a package including direct copper wire bonding on a partially pulse-plated bond pad, in accordance with various examples.

FIGS. 4A1-4I3 are a process flow for manufacturing a package including partially pulse-plated bond pads, in accordance with various examples.

FIG. 5A is a profile, cross-sectional view of a wire bond directly coupled to a polycrystalline copper structure.

FIG. 5B is a profile, cross-sectional view of a wire bond directly coupled to a nanotwin copper structure, in accordance with various examples.

FIG. 6 is a block diagram of an electronic device containing a package having partially pulse-plated bond pads, in accordance with various examples.

### DETAILED DESCRIPTION

Packages often include bond wires, which connect metal members on the device side (i.e., the circuitry side) of a semiconductor die to various structures within the package, such as conductive terminals (e.g., package leads). In this way, the bond wires provide power and/or data signals between the die and the conductive terminals of the package. When forming bonds on the metal members of the die, corrosion or pad oxidation and adhesion can present challenges. A metal stack of nickel and palladium, deposited on the top surface of these metal members of the die, has been useful to mitigate electromigration and to facilitate adhesion to wire bonds. Palladium, however, is expensive, and removing the nickel and palladium is not practical, as the underlying copper of the metal member of the die is of a polycrystalline structure that does not bond well to other copper structures, such as wire bonds. This poor bondability between copper wire bonds and copper metal members is due to a variety of factors, such as corrosion and poor diffusibility of copper in polycrystalline copper applications. It is common to achieve bond areas of less than 60% in copper-to-polycrystalline copper bonding applications. The copper metal members may be entirely formed by pulse-plating, thereby producing nanotwin copper members that encourage bondability to copper wire bonds. However, pulse plating is a time-consuming process, and the time required to pulse-plate an entire copper metal member of typical thickness is substantial.

This disclosure describes various examples of packages in which copper wire bonds are formed directly on nanotwin copper members of the package, such as nanotwin copper members formed on the semiconductor die within the package. Nanotwin copper members include horizontally-oriented twin boundaries that separate multiple regions of a copper member from each other, with each of the multiple regions having a different grain structure. These nanotwin copper members are significantly more amenable to direct copper-to-copper bonding, relative to polycrystalline copper structures. Direct copper-to-nanotwin copper bonds eliminate the need for nickel and palladium plating while improving diffusibility. It is common to achieve bond areas of greater than 80% in copper-to-nanotwin copper bonding applications. In examples, a package comprises a semiconductor die including a device side having circuitry formed therein. The package includes a metal member coupled to the device side, with the metal member in vertical alignment with circuitry on the device side. The package also includes a copper member having a bottom surface coupled to the metal member, and a top surface opposite the bottom surface. The copper member comprises a direct-plated, polycrystalline copper portion and a pulse-plated, nanotwin copper portion. The polycrystalline copper portion extends through virtually the entire thickness of the copper member, except for the nanotwin copper portion, which is positioned at the top surface of the copper member and is only a few microns (i.e., between 0.5 microns and 3 microns) thick. The nanotwin copper portion of the copper member comprises a twin boundary separating a first region having a first grain structure from a second region having a second grain structure. The twin boundary is horizontally oriented and is approximately parallel with a horizontal plane in which the semiconductor die lies. The package also includes a wire bond coupled directly to the top surface (i.e., the nanotwin portion) of the copper member. The package further comprises a mold compound covering the die, the metal member, the copper member, and the wire bond.

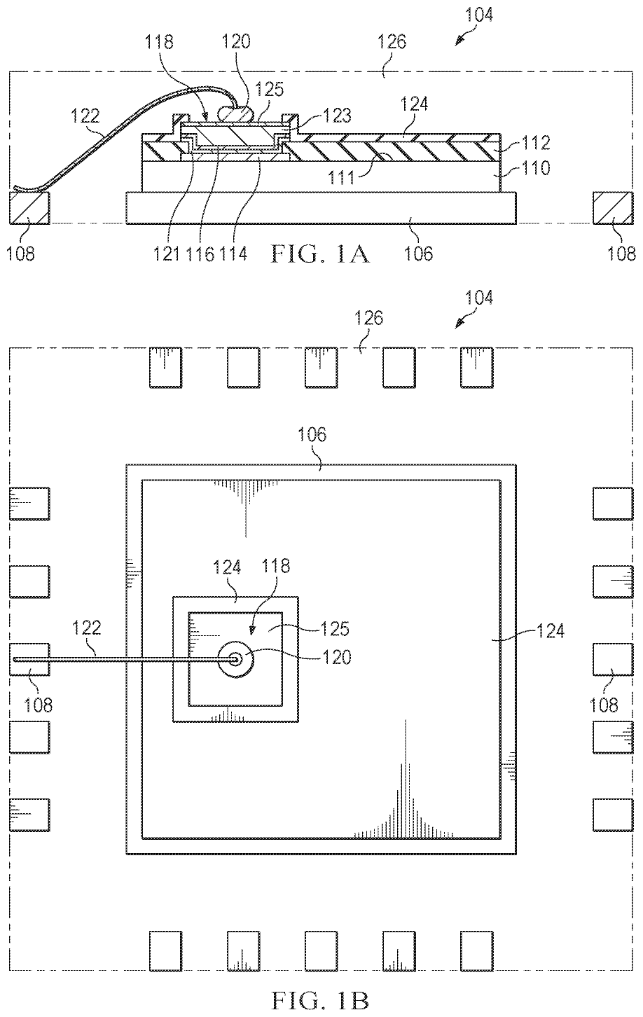

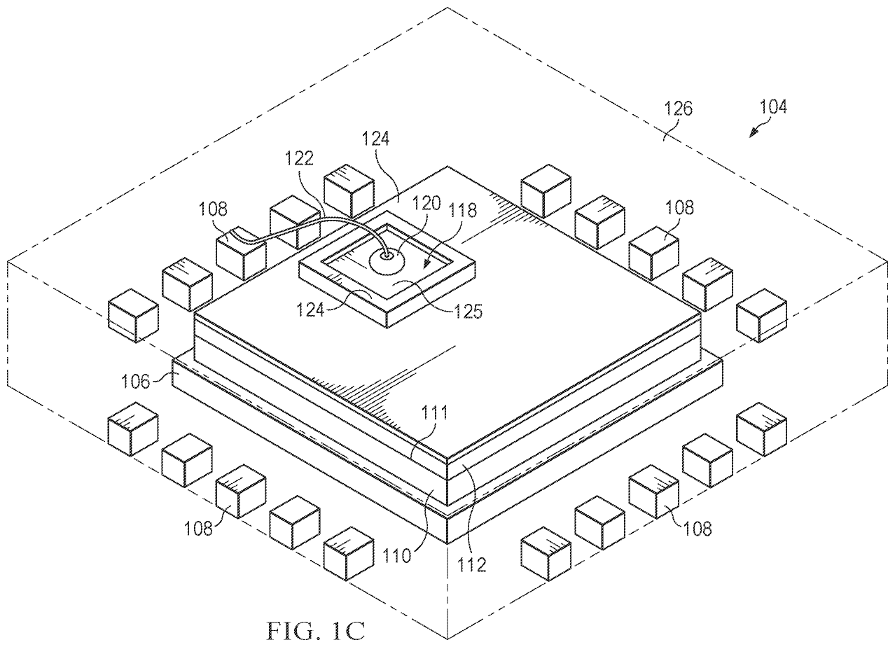

FIG. 1A is a profile, cross-sectional view of a package 104 including direct copper wire bonding on a partially pulse-plated bond pad, in accordance with various examples. In particular, the package 104 includes a die pad 106 and conductive terminals 108. Although the package 104 is depicted as a quad flat no lead (QFN) package, the package 104 may be any suitable type of package in which copper bond pads are coupled to other copper components, such as wire bonds. The package 104 includes a semiconductor die 110 coupled to the die pad 106, for example using a die attach material. The semiconductor die 110 includes a device side 111 in which circuitry is formed. A metal member 114 is coupled to the device side 111—for example, to metallization on the device side 111 that couples to circuitry of the semiconductor die 110. A sputtered barrier layer 121 (e.g., titanium-tungsten, titanium) contacts the metal member 114. A sputtered seed layer 116 contacts the barrier layer 121. A copper member 118 contacts the seed layer 116. As described in greater detail below, the copper member 118 includes a direct-plated, polycrystalline copper portion 123 and a pulse-plated, nanotwin copper portion 125. Accordingly, the copper member 118 is said to be partially pulse-plated. An insulative layer 112, such as a passivation layer, contacts the device side 111 and the metal member 114. An insulative layer 124, such as a polyimide layer, may contact the insulative layer 112 and the copper member 118. A wire bond 120 (e.g., a ball bond, such as a copper ball bond) is bonded to the copper member 118, and more specifically, to the nanotwin copper portion 125. A bond wire 122 is coupled to the wire bond 120 and to one of the conductive terminals 108. A mold compound 126 covers the various structures described above, as shown. The conductive terminals 108 are exposed to an exterior of the mold compound 126, as shown. The stack including the metal member 114, the barrier layer 121, the seed layer 116, and the copper member 118 docs not include nickel or palladium. FIG. 1B is a top-down view of the structure of FIG. 1A, in accordance with various examples. FIG. 1C is a perspective view of the structure of FIG. 1A, in accordance with various examples.

Still referring to FIGS. 1A-IC, the copper member 118 provides multiple benefits and solves technical challenges. For example, the pulse-plated, nanotwin copper portion 125 at the top surface of the copper member 118 facilitates direct bonding to a copper structure, such as the copper wire bond 120. Plated layers such as nickel and palladium are excluded, thus reducing manufacturing time, complexity, and cost, as well as reducing package structure size and weight. Further, not all of the copper member 118 is pulse-plated. Rather, the copper member 118 is partially pulse-plated, meaning that the portion of the copper member 118 that is not bonded to the wire bond 120 and thus does not need to be nanotwin copper and instead may be polycrystalline copper is formed using direct-plating techniques. Consequently, the majority of the copper member 118 comprises the polycrystalline copper portion 123 (i.e., the nanotwin copper portion 125 is between 10% and 20% of the volume of the copper member 118, with a composition below this range being disadvantageous because there will not be enough nanotwin copper to facilitate copper to copper diffusion, and with a composition above this range being disadvantageous because the plating cycle time will increase, since the pulse plating required for forming the nanotwin copper takes longer and nanotwin copper that is not present at the surface of the copper member 118 is not involved in bond formation, and thus the polycrystalline copper portion 123 is between 80% and 90% of the volume of the copper member 118). The nanotwin copper portion 125, which is positioned at the top surface of the copper member 118, is only 0.5 microns to 3 microns thick, with a thickness below this range being disadvantageous because there will be insufficient nanotwin copper to facilitate the copper to copper diffusion, and with a thickness above this range being disadvantageous because the plating cycle time will increase, since the pulse plating required for forming the nanotwin copper takes longer and nanotwin copper that is not present at the surface of the copper member 118 is not involved in bond formation.

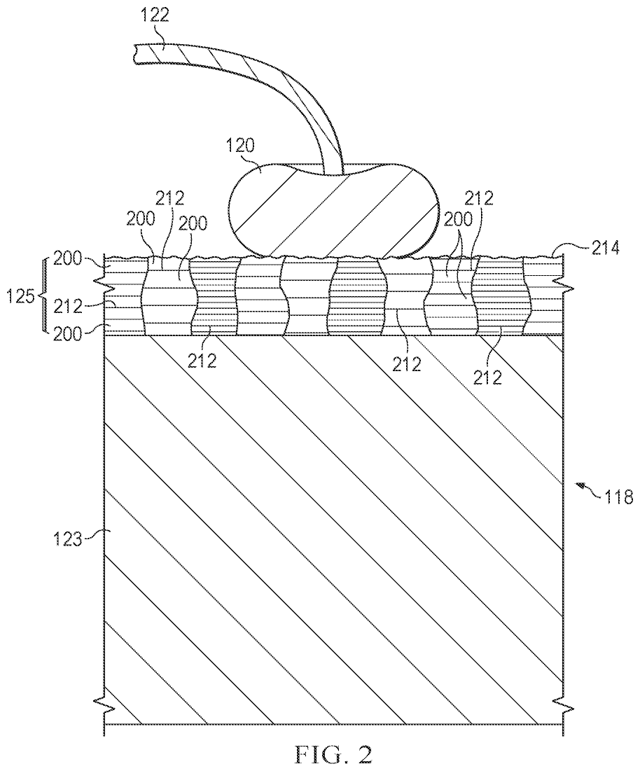

FIG. 2 is a profile, cross-sectional view of the wire bond 120 coupled to the nanotwin copper portion 125 of the partially pulse-plated copper member 118, in accordance with various examples. The nanotwin copper portion 125 includes nanoscale twin boundaries separating the copper grains of the nanotwin copper portion 125. Twin boundaries are planar defects that separate two regions of a crystal that have a very similar, or mirror, image relationship to each other. In nanotwin copper, these twin boundaries are highly dense and closely spaced. In FIG. 2, the nanotwin copper portion 125 includes regions 200 separated by respective twin boundaries 212. The twin boundaries 212 are horizontally oriented, as shown, and are approximately parallel to the horizontal plane in which the semiconductor die 110 (FIG. 1A) lies. As used herein, approximately parallel means parallel or within plus or minus 10 degrees from parallel. Each region 200 has a different grain structure, with the twin boundaries 212 separating respective pairs of regions 200 having mirror-image grain structures.

The wire bond 120 is bonded to a surface 214 of the copper member 118 (i.e., of the nanotwin copper portion 125). The wire bond 120 is bonded to two or more regions 200 of the nanotwin copper portion 125. Relative to polycrystalline copper, the nanotwin copper of the nanotwin copper portion 125 forms superior direct bonds to other copper structures (e.g., copper ball bonds, such as the wire bond 120) by improving diffusibility between the nanotwin copper portion 125 and the wire bond 120. This superior diffusibility is possible because nanotwin copper has a (111) plane orientation, which has the highest diffusivity amongst all crystal orientations. Direct copper-to-nanotwin copper bonds eliminate the need for nickel and palladium plating while improving diffusibility. Polycrystalline copper portion 123 contacts and underlies nanotwin copper portion 125, as shown.

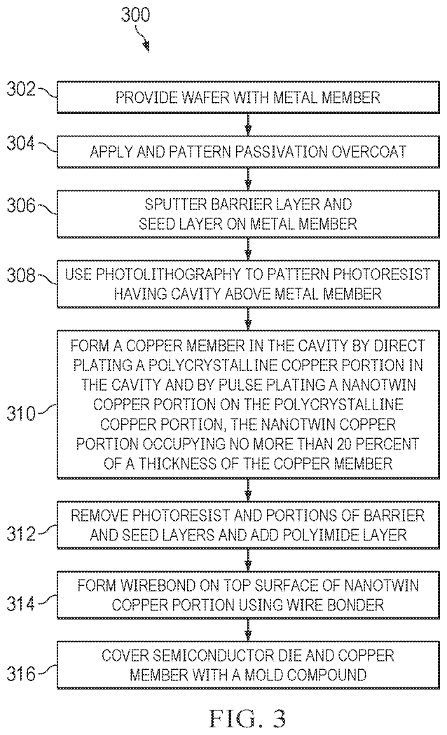

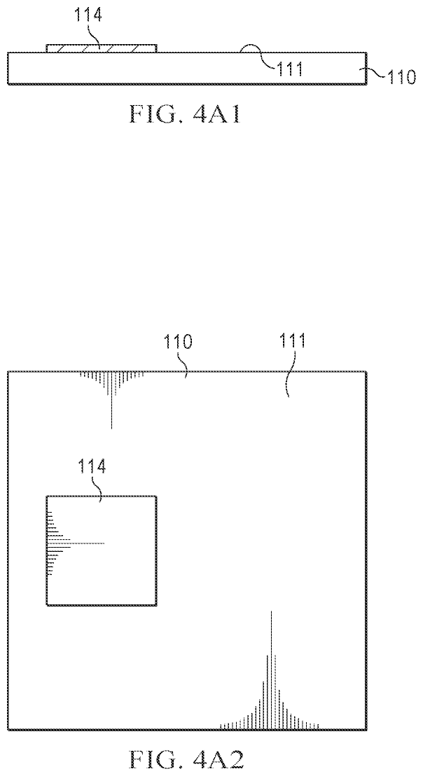

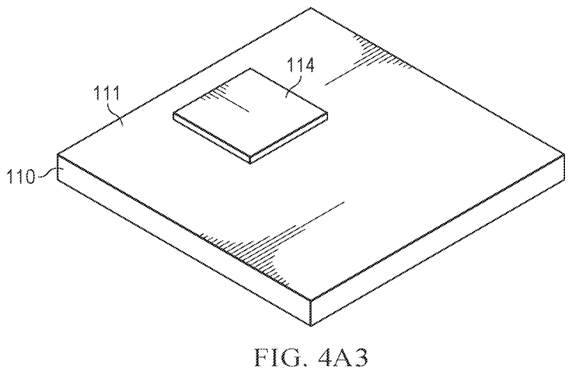

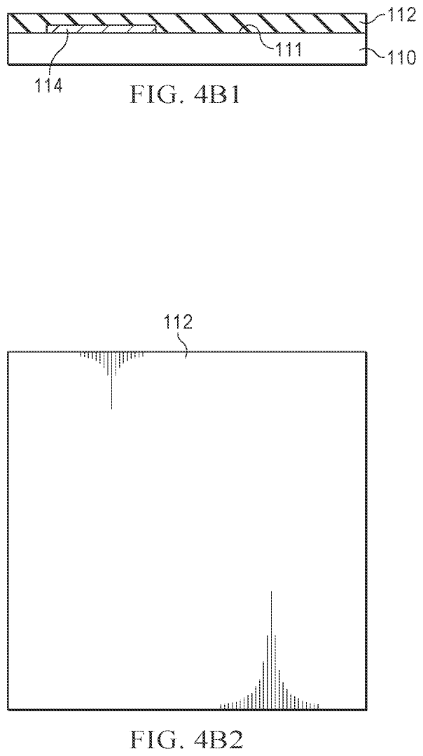

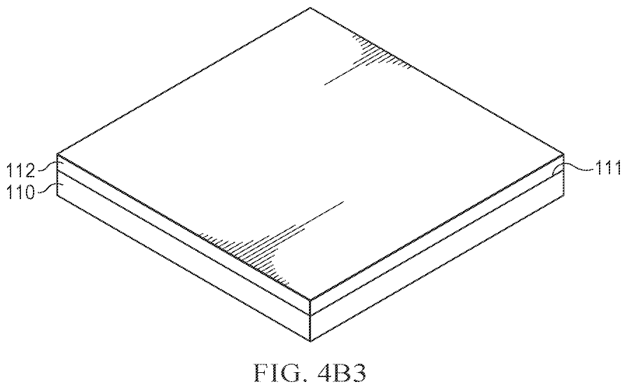

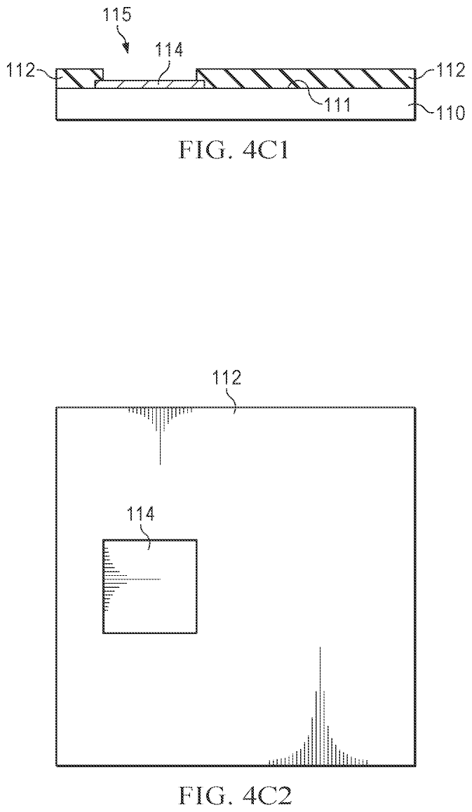

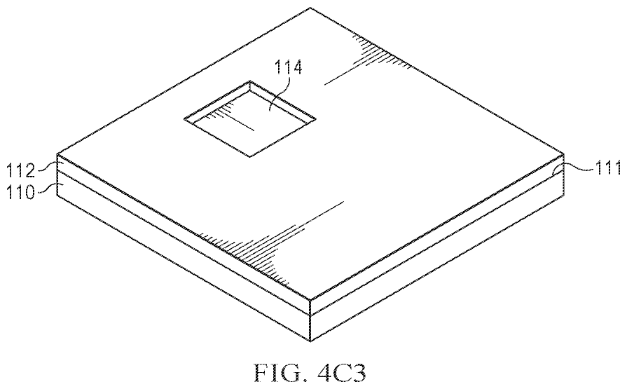

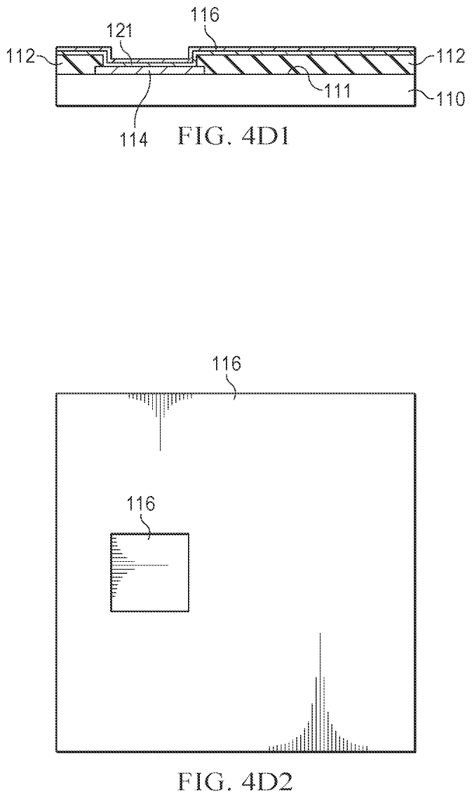

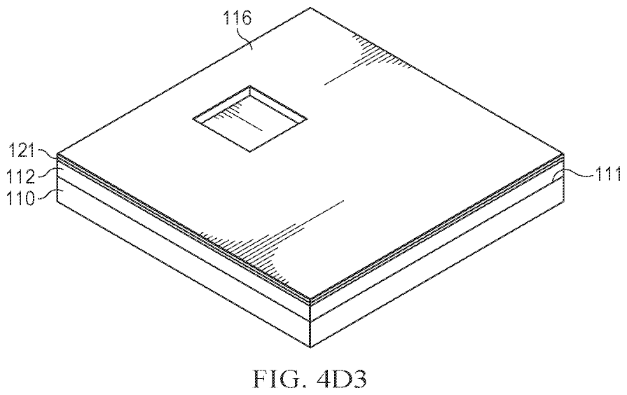

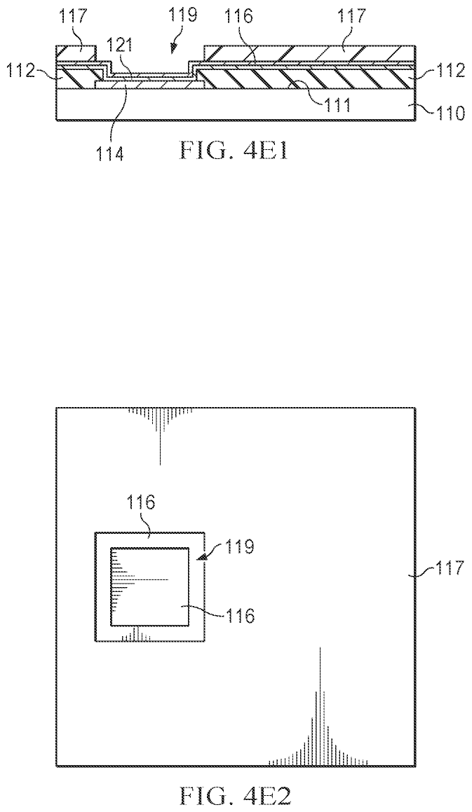

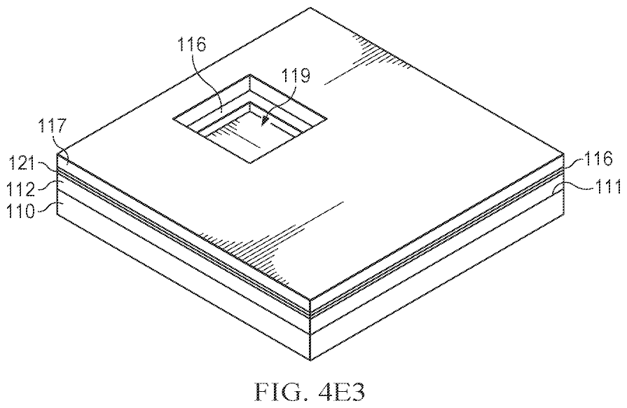

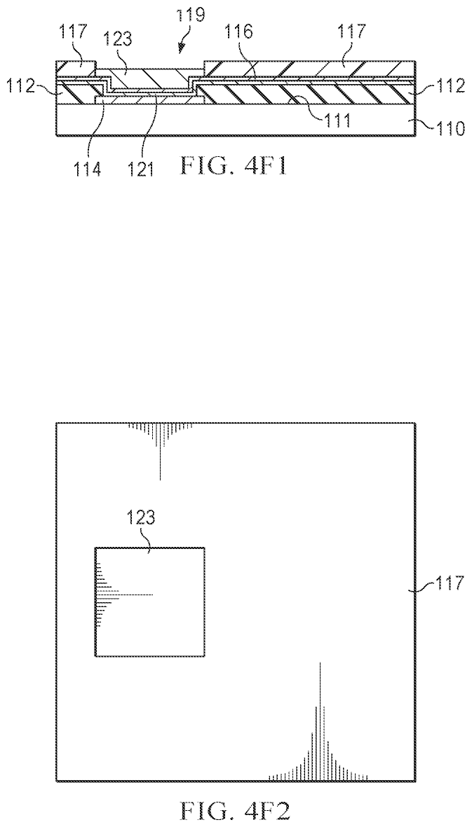

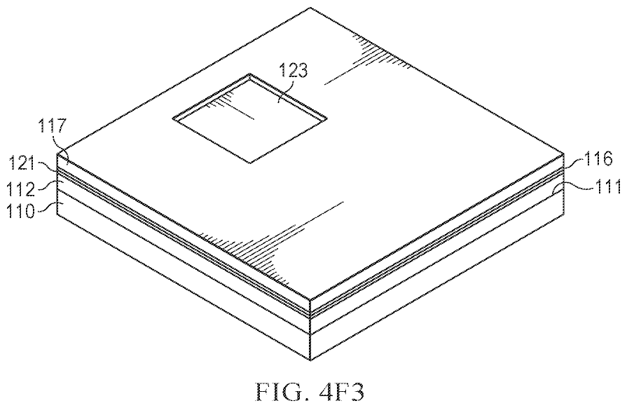

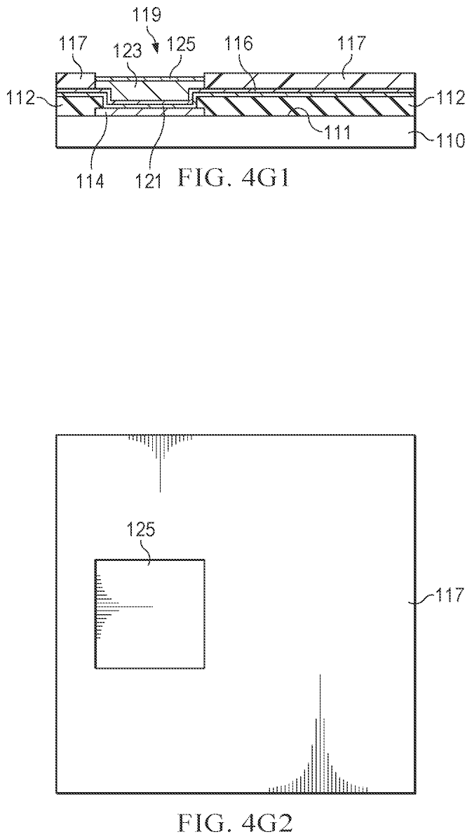

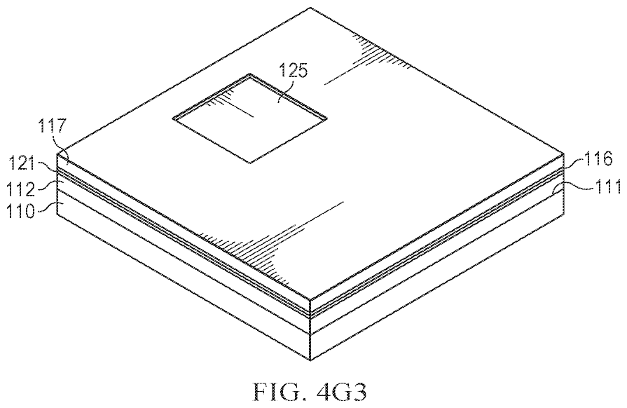

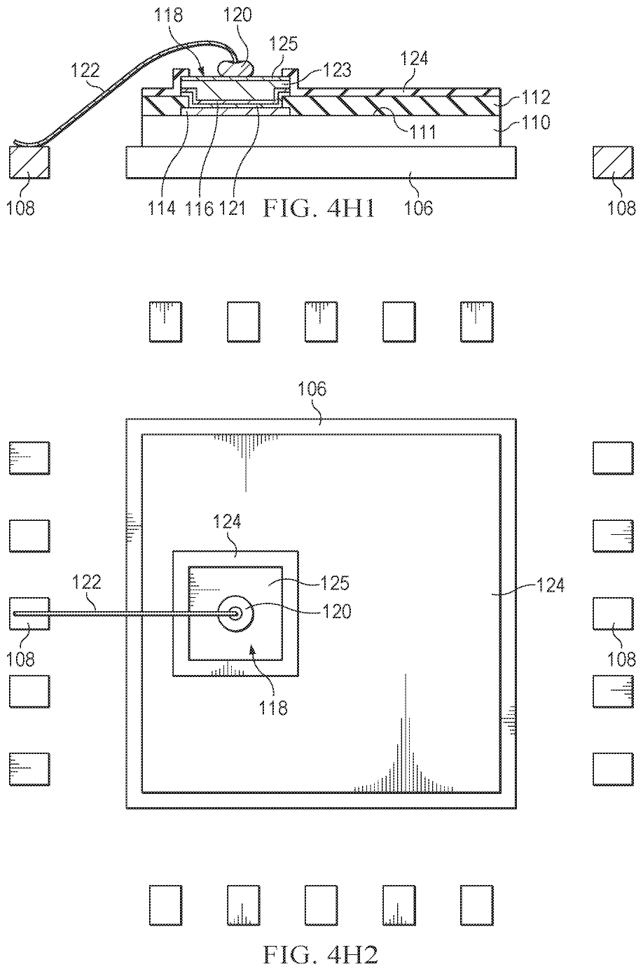

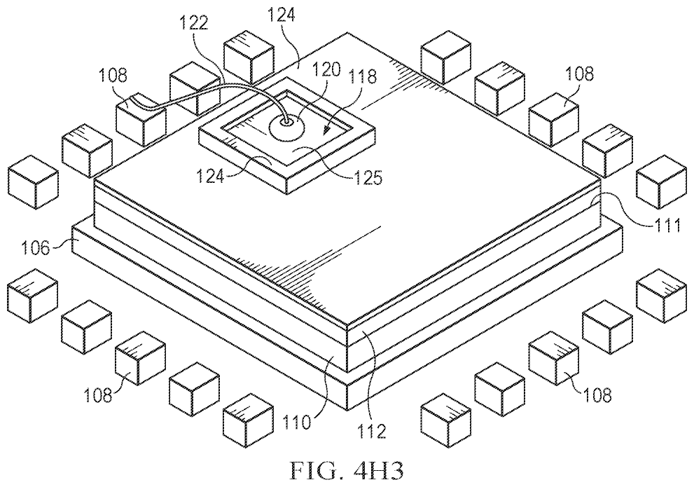

FIG. 3 is a flow diagram of a method 300 for manufacturing a package including direct copper wire bonding on a partially pulse-plated bond pad, in accordance with various examples. FIGS. 4A1-4I3 are a process flow for manufacturing a package including partially pulse-plated bond pads, in accordance with various examples. Accordingly, FIGS. 3 and 4A1-4I3 are now described in parallel.

The method 300 begins with providing a semiconductor wafer with a metal member positioned on a device side of the wafer (302). FIG. 4A1 is a profile, cross-sectional view of a semiconductor wafer 110 having a metal member 114 positioned on the device side 111 of the wafer 110. The device side 111 is the side of the wafer 110 in which circuitry is formed. Although the numeral 110 is used herein to denote a semiconductor die, for case of explanation, the numeral 110 may also be used to denote a semiconductor wafer that is subsequently singulated to produce the semiconductor die 110. FIG. 4A2 is a top-down view of the structure of FIG. 4A1, in accordance with various examples. FIG. 4A3 is a perspective view of the structure of FIG. 4A1, in accordance with various examples.

The method 300 includes applying and patterning a passivation overcoat (304). FIG. 4B1 is a profile, cross-sectional view of the structure of FIG. 4A1, except with the addition of the insulative layer 112 (e.g., a passivation overcoat layer). The insulative layer 112 contacts the metal member 114 and the device side 111, as shown. FIG. 4B2 is a top-down view of the structure of FIG. 4B1, in accordance with various examples. FIG. 4B3 is a perspective view of the structure of FIG. 4B1, in accordance with various examples. FIG. 4C1 shows the structure of FIG. 4B1, except that an opening 115 is formed in the insulative layer 112 above the metal member 114 (e.g., using photolithography techniques). FIG. 4C2 is a top-down view of the structure of FIG. 4C1, in accordance with various examples. FIG. 4C3 is a perspective view of the structure of FIG. 4C2, in accordance with various examples.

The method 300 includes sputtering a barrier layer on the metal member and a seed layer on the barrier layer (306). FIG. 4D1 shows the structure of FIG. 4C1, except that the barrier layer 121 is applied to the insulative layer 112 and the metal member 114, and the seed layer 116 is applied to the barrier layer 121. The barrier layer 121 comprises titanium or a titanium-tungsten alloy, and the seed layer 116 is a copper seed layer. FIG. 4D2 is a top-down view of the structure of FIG. 4D1, in accordance with various examples. FIG. 4D3 is a perspective view of the structure of FIG. 4D1, in accordance with various examples.

The method 300 includes using photolithography to pattern a photoresist having a cavity above the metal member (308). FIG. 4E1 is a profile, cross-sectional view of the structure of FIG. 4D1, except that a photoresist layer 117 is applied to the seed layer 116, and photolithography techniques are used to form a cavity 119 above the metal member 114, as shown. FIG. 4E2 is a top-down view of the structure of FIG. 4E1, in accordance with various examples. FIG. 4E3 is a perspective view of the structure of FIG. 4E1, in accordance with various examples.

The method 300 includes forming a copper member in the cavity by direct plating a polycrystalline copper portion in the cavity and by pulse plating a nanotwin copper portion on the polycrystalline copper portion (310). As described above, the nanotwin copper portion occupies between 10% and 20% of a volume of the copper member (310). FIG. 4F1 is a profile, cross-sectional view of the structure of FIG. 4E1, except that a portion of the copper member 118—and more specifically, the polycrystalline copper portion 123—is formed in the cavity 119. The polycrystalline copper portion 123 is formed by a direct electroplating technique. FIG. 4F2 is a top-down view of the structure of FIG. 4F1, in accordance with various examples. FIG. 4F3 is a perspective view of the structure of FIG. 4F2, in accordance with various examples.

FIG. 4G1 is a profile, cross-sectional view of the structure of FIG. 4F1, except that the nanotwin copper portion 125 of the copper member 118 is formed in the cavity 119, on top of the polycrystalline copper portion 123. The nanotwin copper portion 125 is formed by a pulsed electroplating technique. As described, the thickness of the nanotwin copper portion 125 is between 10% and 20% of the total volume of the copper member 118. The nanotwin copper portion 125 has a thickness in the range provided above. FIG. 4G2 is a top-down view of the structure of FIG. 4G1, in accordance with various examples. FIG. 4G3 is a perspective view of the structure of FIG. 4G1, in accordance with various examples. Furthermore, the aforementioned titanium barrier layer 121 may orient the sputtered copper seed layer 116 to a (111) plane orientation, and during electroplating, this (111) plane orientation may act as a precursor material to form the nanotwin copper.

Specific parameters are used when pulse plating the nanotwin copper portion 125 to achieve specific properties of the nanotwin copper portion 125. For example, while pulse plating the nanotwin copper portion 125, electric current is pulsed for only limited periods of time. Specifically, a duty cycle between 25% and 50% is used to pulse plate the nanotwin copper portion 125, with a lower duty cycle making the plating time unacceptably long, and with a higher duty cycle being unacceptably inefficient.

The method 300 includes removing the photoresist and portions of the barrier and seed layers, and optionally applying a polyimide layer (312). The method 300 also includes forming a wire bond on the top surface of the nanotwin copper portion after the structure of FIG. 4G1 is coupled to a die pad using a die attach material (314). FIG. 4H1 is a profile, cross-sectional view of the structure of FIG. 4G1, except that the photoresist layer 117 is stripped, the portions of the seed layer 116 that are not directly beneath the copper member 118 are etched away, and the insulative layer 124 (e.g., a polyimide layer) is applied to contact the insulative layer 112 and the copper member 118, as shown. FIG. 4H1 also depicts the bonding of the wire bond 120 to the top surface of the copper member 118 (i.e., the nanotwin copper portion), with the bond wire 122 bonded to one of the conductive terminals 108, such as by a stitch bond. FIG. 4H2 is a top-down view of the structure of FIG. 4H1, in accordance with various examples. FIG. 4H3 is a perspective view of the structure of FIG. 4H1, in accordance with various examples.

Forming the wire bond 120 includes using a wire bonding temperature ranging between 90 degrees Celsius and 120 degrees Celsius, with a temperature below this range being disadvantageous because no bond can be formed because low temperature bonding is still driven by diffusion which is accelerated by temperature, and with a temperature above this range being disadvantageous because oxidation of the pad can occur during the wire bonding process and inhibit good bond formation. During a first wire bonding time segment, a wire bonder is used to apply a first force on the top surface of the copper member 118 for a first length of time, with the first force ranging between 15 grams and 25 grams, and the first length of time ranging between 1 millisecond and 5 milliseconds. During a second wire bonding time segment after the first wire bonding time segment, the wire bonder is used to apply a second force on the top surface of the copper member 118 while scrubbing the top surface of the copper member 118, with the second force ranging between 15 grams and 25 grams. During a third wire bonding time segment after the second wire bonding time segment, the wire bonder is used to apply a third force on the top surface of the copper member 118 for a second length of time, with the third force ranging between 45 grams and 55 grams, and with the second length of time ranging between 15 milliseconds and 25 milliseconds. The ultrasonic energy applied during the third wire bonding time segment is greater than an ultrasonic energy applied during the second wire bonding time segment. The ultrasonic energy applied during the second wire bonding time segment is greater than an ultrasonic energy applied during the first wire bonding time segment.

The method 300 includes covering the semiconductor die and copper member with a mold compound (316). FIG. 411 is a profile, cross-sectional view of the structure of FIG. 4H1, except that a mold compound 126 is applied to cover the various structures shown in FIG. 4H1. The conductive terminals 108 are exposed to an exterior of the mold compound 126. FIG. 412 is a top-down view of the structure of FIG. 411, in accordance with various examples. FIG. 413 is a perspective view of the structure of FIG. 411, in accordance with various examples.

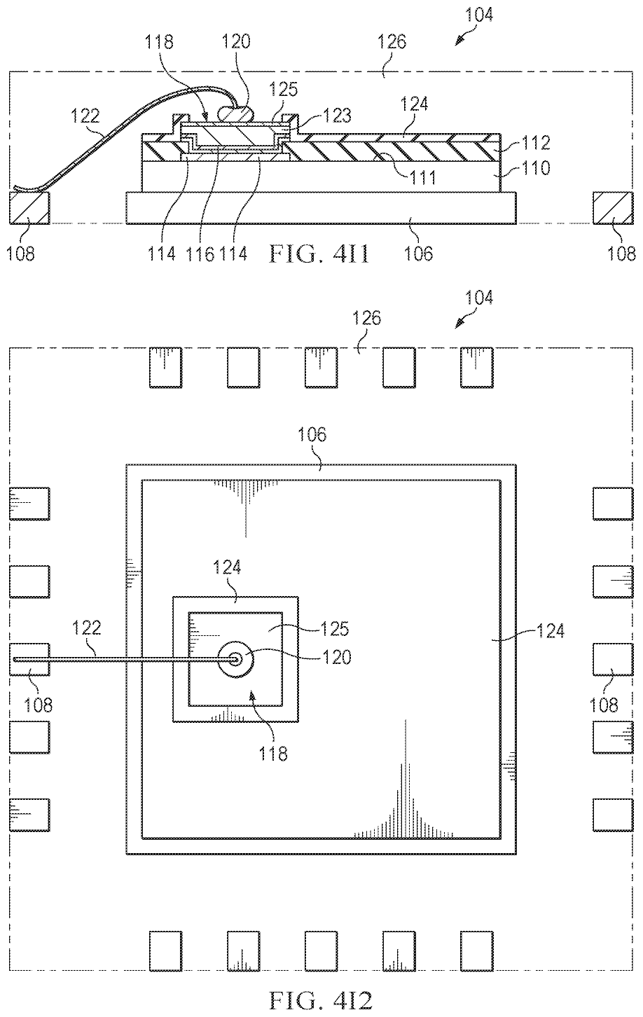

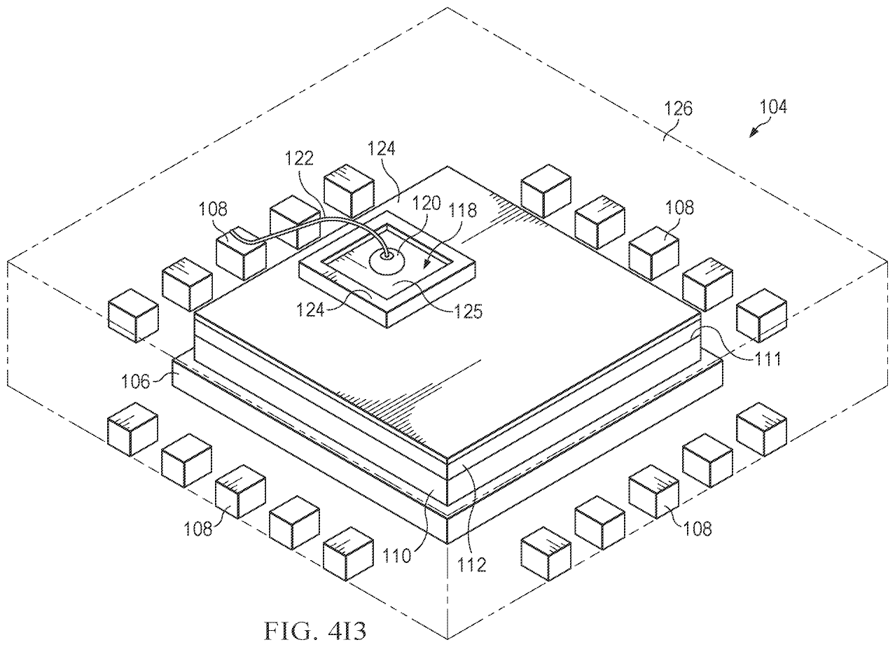

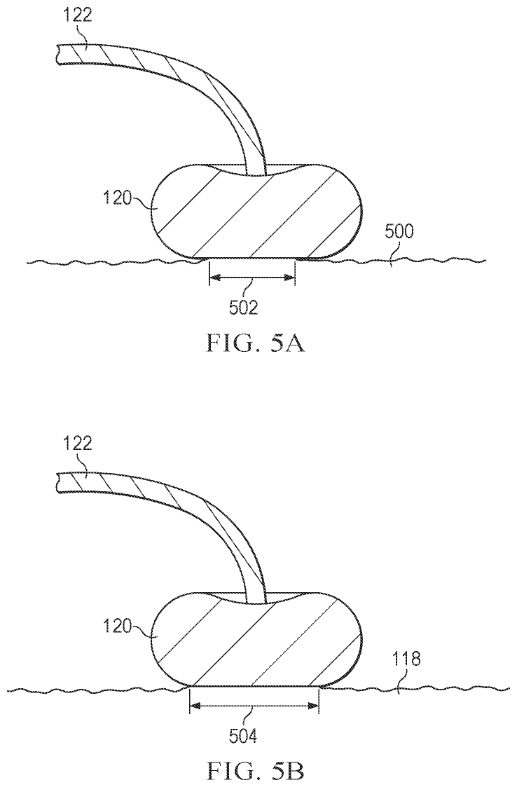

FIG. 5A is a profile, cross-sectional view of a wire bond directly coupled to a polycrystalline copper structure 500. The term “directly coupled,” and variations thereof, as used herein means a component contacting another component with no other components or materials therebetween. As explained, polycrystalline copper is inferior to nanotwin copper in terms of diffusibility and, thus, bondability to copper structures, such as wire bonds. Thus, the wire bond 120 forms a bond with the polycrystalline copper structure 500 that has a bond area 502 of only 56% of the total bondable area of the wire bond 120. This means that of the surface area of the wire bond 120 that could bond to the polycrystalline copper structure 500, only 56% of that surface area successfully bonds to the polycrystalline copper structure 500. In contrast, FIG. 5B is a profile, cross-sectional view of the wire bond 120 directly coupled to the copper member 118 (i.e., to the nanotwin copper portion 125), in accordance with various examples. The wire bond 120 has a superior bond area 504 of at least 89% with the copper member 118, because the wire bond 120 is coupled to nanotwinned copper.

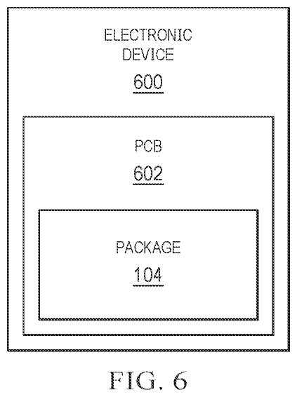

FIG. 6 is a block diagram of an electronic device 600 containing a package 104 having partially pulse-plated bond pads as described herein, in accordance with various examples. The package 104 may be coupled to a printed circuit board (PCB) 602.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A package, comprising:
a semiconductor die including a device side having circuitry formed therein;
a metal member coupled to the device side;
a copper member having a bottom surface coupled to the metal member and a top surface opposite the bottom surface, the copper member including at the top surface a nanotwin copper portion having a thickness between 0.5 microns and 3 microns, the copper member including a polycrystalline copper portion contacting the nanotwin copper portion and extending to the bottom surface, the nanotwin copper portion comprising a twin boundary separating a first region having a first grain structure from a second region having a second grain structure;
a wire bond coupled directly to the nanotwin copper portion of the copper member, the wire bond contacting multiple regions of the nanotwin copper portion; and
a mold compound covering the semiconductor die, the metal member, the copper member, and the wire bond.

2. The package of claim 1, wherein the thickness of the nanotwin copper portion ranges between 10% and 20% of a volume of the copper member.

3. The package of claim 2, wherein the thickness of the polycrystalline copper portion ranges between 80% and 90% of the volume of the copper member.

4. The package of claim 1, wherein at least 89% of a bottom surface of the wire bond is bonded to the nanotwin copper portion, the bottom surface of the wire bond facing the nanotwin copper portion.

5. The package of claim 1, wherein the package does not include a nickel layer in a same metal stack as the polycrystalline and nanotwin copper portions.

6. The package of claim 1, wherein the package does not include a palladium layer in a same metal stack as the polycrystalline and nanotwin copper portions.

7. The package of claim 1, wherein the twin boundary is oriented approximately parallel to a horizontal plane in which the semiconductor die lies.

8. The package of claim 1, wherein the nanotwin copper portion is pulse-plated.

9. The package of claim 1, wherein the polycrystalline copper portion is direct-plated.

10. A package, comprising:
a semiconductor die including a device side having circuitry formed therein;
a metal member coupled to the device side;
a copper member having a bottom surface coupled to the metal member and a top surface opposite the bottom surface, the copper member including a polycrystalline copper portion composing 80% to 90% of a volume of the copper member and a nanotwin copper portion composing 10% to 20% of the volume of the copper member;
a wire bond coupled directly to the nanotwin copper portion of the copper member, the wire bond contacting multiple regions of the nanotwin copper portion; and
a mold compound covering the semiconductor die, the metal member, the copper member, and the wire bond.

11. The package of claim 10, wherein the nanotwin copper portion has a thickness ranging between 0.5 microns and 3 microns.

12. The package of claim 10, wherein the wire bond contacts multiple regions of the nanotwin copper portion, each of the multiple regions having differing grain structures.

13. The package of claim 10, wherein at least 89% of a bottom surface of the wire bond is bonded to the nanotwin copper portion, the bottom surface of the wire bond facing the nanotwin copper portion.

14. The package of claim 10, wherein the package does not include a nickel layer in a same metal stack as the polycrystalline and nanotwin copper portions.

15. The package of claim 10, wherein the package does not include a palladium layer in a same metal stack as the polycrystalline and nanotwin copper portions.

16. The package of claim 10, wherein the nanotwin copper portion is pulse-plated.

17. The package of claim 10, wherein the polycrystalline copper portion is direct-plated.

18. A method for manufacturing a package, comprising:
sputtering a seed layer above a metal member, the metal member coupled to a semiconductor die;
using photolithography to pattern a photoresist having a cavity above the metal member;
forming a copper member in the cavity by direct plating a polycrystalline copper portion in the cavity and by pulse plating a nanotwin copper portion on the polycrystalline copper portion, the nanotwin copper portion occupying no more than 20% of a volume of the copper member;
forming a wire bond on a top surface of the nanotwin copper portion using a wire bonder; and
covering the semiconductor die and the copper member with a mold compound.

19. The method of claim 18, wherein the pulse plating comprises pulsing electrical current during only a subset of a time during which the nanotwin copper portion is plated.

20. The method of claim 18, wherein the nanotwin copper portion has a thickness ranging from 0.5 microns to 3 microns.

21. The method of claim 18, wherein the nanotwin copper portion comprises a twin boundary separating a first region having a first grain structure from a second region having a second grain structure.

22. The method of claim 21, wherein the twin boundary is oriented approximately parallel to a horizontal plane in which the semiconductor die lies.
